(19) United States
(12) Patent Application Publication
(10) Pub. No.: US 2019/0067049 A1
(43) Pub. Date: Feb. 28, 2019

(54) RADIATIVE WAFER CUTTING USING SELECTIVE FOCUSING DEPTHS

(71) Applicant: ASM Technology Singapore Pte Ltd, Singapore (SG)

(72) Inventors: Chi Wah CHENG, Hong Kong (HK); Lap Kei CHOW, Hong Kong (HK); Chi Hang KWOK, Hong Kong (HK)

(21) Appl. No.: 15/683,904

(22) Filed: Aug. 23, 2017

(51) Int. Cl. H01L 21/67; B23K 26/035; B23K 26/046; B23K 26/067; B23K 26/08; H01L 21/687; H01L 21/268; H01L 21/78

(52) U.S. Cl. CPC H01L 21/67092; B23K 26/035; B23K 26/046; H01L 21/78; B23K 26/083; H01L 21/68764; H01L 21/268; B23K 26/0673

(57) ABSTRACT

Semiconductor wafer cutting is optimised by directing a plurality of laser beams at the wafer, with the laser beams being focused so that at least some of their respective focal points are located at different depths throughout the wafer.

This invention relates to a laser cutting apparatus and a method of cutting a planar semiconductor wafer.

### BACKGROUND AND PRIOR ART

Singulation and scribing are well-known processes in the semiconductor industry, in which a cutting machine is used to work a workpiece or substrate such as a semiconductor wafer, which could for example comprise silicon but is not so limited. Throughout this specification, the term “wafer” is used to encompass all these products. In a singulation process (also referred to as dicing, severing, cleaving for example), a wafer is completely cut through such as to singulate the wafer into individual dies. In a scribing process (also referred to as grooving, scoring, gouging or furrowing for example), a channel or groove is cut into a wafer. Other processes may be applied subsequently, for example full singulation by using a physical saw along the cut channels. Throughout the present specification, the term “cutting” will be used to encompass both singulation and scribing.

Silicon semiconductor wafers are conventionally of the order of 0.1 mm to 1 mm thick. Recently, semiconductor manufacturers have started to migrate to the use of “thin” wafers, which will here be defined as wafers having a thickness of less than 200 μm. Singulation of such thin wafers requires special approaches, for example as described in U.S. Pat. No. 8,785,298.

On the other extreme, there are also demands in processing “thick” wafers (i.e. those over 200 μm thick) in various applications, such as moulded wafer, ceramic sub-mount, etc. The use of a thicker wafer may also lead to a cost reduction, due to the reduced lapping (thinning) time of sapphire substrates in LED manufacturing processes for example.

Since thin semiconductor devices may have their mechanical strengths increased through the encapsulation of epoxy moulding compound on five or six sides, having a thickness in a typical range of 200 μm-2000 μm, and commonly in a range of 200 μm-800 μm, singulation techniques for thick semiconductors may also be relevant for such encapsulated devices.

Conventionally, where physical constraints such as chipping, delamination and large kerf width are less demanding, a blade saw is used for singulation of thick wafers. As the dicing “street” width becomes narrower, the demand on the singulation quality becomes correspondingly higher. To meet this demand, laser dicing is becoming an emerging solution for the singulation of thick wafers whilst maintaining an acceptable device yield and visual quality. More specifically, it has been observed that if a thick wafer is mechanically singulated using a blade saw, many of the singulated devices emerge from the singulation process in a mechanically broken state. For instance, obvious advantages in dicing quality and precision are observed for moulded silicon wafers which are radiatively singulated using a laser beam, compared to those mechanically singulated using a blade saw, due to a narrower kerf width achievable by such radiative singulation.

It has been proposed to use a multiple beam laser singulation approach, for example in WO 1997/029509 A1, in which a linear cluster of focused laser beams cooperate to form a linear array of laser spots, is used to ablate substrate material along a scribeline, thus causing the substrate to be radiatively scored along the line of ablation. The use of multiple beams in this manner as opposed to a single (more powerful) beam can help to produce a narrower ablation tract on the substrate. This can have certain advantages, particularly when the scribeline in question is in close proximity to devices which may be fragile and expensive, on a semiconductor substrate. For thick wafers, the substrate material along a scribeline is removed successively by multiple passes of such an array of focused spots.

Various known radiative cutting schemes are schematically shown in FIGS. 1 to 8. Many of the figures reference a co-ordinate system—as is conventional in the art, the X-Y plane is that which is parallel to the plane of the planar semiconductor wafer being cut, which will generally be horizontal. The Z-axis extends normal to the X-Y plane, i.e. generally in the vertical direction. FIG. 1 shows a sectional view of part of a laser cutting apparatus, including a wafer table 1 on which an uncut thick planar semiconductor wafer 2 is supported. Interposed between the wafer table 1 and wafer 2 is an adhesive carrying-foil 3, such as a commercially available dicing tape, on which the wafer 2 is adhered. The wafer 2 has two substantially parallel major surfaces 4, 5, that are separated from one another by a thickness T in the range from 200 μm to 2000 μm. The wafer 2 is mounted so that its second major surface 5 contacts the foil 3, while its first major surface 4 is presented (in the Z direction) to a radiative scribing tool. The foil may, for example, be spanned within a circumferential frame (not shown) that is clamped to the table. FIG. 2 is a similar view to FIG. 1, but taken while a singulating cutting process is ongoing. A number of through-cuts have been made along cut or scribe lines 6 by an incident laser beam 7. The cut lines 6 extend in a grid formation along both X and Y directions, as can be more clearly seen in FIG. 5 described below. Since this is a singulation process, the depth D of the cut will eventually reach the thickness T of the wafer 2, i.e. the entire thickness of the wafer is cut, by conducting multiple passes or using multiple laser beams. This allows separation of devices along the cut lines.

FIGS. 3 and 4 correspond to FIGS. 1 and 2, but show an alternative configuration in which a thick semiconductor wafer 2 is supported on a wafer-carrying jig 8, to which the wafer is adhered by application of a vacuum. The jig 8 is mounted on a wafer table 1. The second major surface 5 of the wafer 2 contacts the wafer-carrying jig 8, whereas its first major surface 4 is presented to a radiative scribing tool. The wafer-carrying jig 8 keeps the singulated devices in place on the wafer table 1.

FIG. 5 schematically shows a cutting methodology for wafer 2. Here, for clarity only four devices 9 are shown for the sake of example, with cut lines 6 separating these. The orthogonal grid structure formed by these lines 6 can be easily seen. The wafer 2 is cut using a “longitudinal scan and lateral step” approach, in which the wafer 2 is cut along multiple, successive cut lines in a particular direction (in this case ±Y). In more detail, the wafer 2 is cut along a cut line 6A by scanning the beam in the −Y direction; in this example, this relative motion is achieved by moving the wafer table using a stage assembly to scan the wafer table in the +Y direction. Alternatively, the wafer table could be kept stationary and the cutting laser beam moved, or both the table and laser beam could be moved.

After completing a cutting run along the cut line 6A, the stage assembly will be used to step the wafer table in the +x direction by an amount ΔX; as a result, the beam will effectively be stepped with respect to the wafer surface by an amount −ΔX.

The wafer 2 is now cut along cut line 6B by scanning the beam in the +Y direction; in practice, this relative motion can be achieved by using the stage assembly to scan the wafer table in the −Y direction. These steps may then be repeated until the entire wafer 2 is singulated.

FIG. 6 schematically shows an enlarged view of wafer 2 in the region of devices 9, while the wafer is being cut along cut line 6B. In particular, FIG. 6 shows that the four devices 9 are mutually separated by two orthogonal dicing streets 10A, 10B. The desired cut line 6B is shown running along one of these dicing streets 10A, extending parallel to the Y-axis and centered within the dicing street 10A with respected to the x-direction. Laser light spots 11, equivalent to the cross-section of the respective laser beam 7 (see FIGS. 2, 4) incident upon the wafer 2, are moved relative to the wafer 2 along the −Y direction (shown as direction D) to ablate the illuminated semiconductor material. In the example shown, there is a simple linear array of four laser spots 11A-D. As each laser spot 11 passes a region of semiconductor devices 9, more semiconductor material is ablated, with the aim that all semiconductor material along the cut line 6B will be ablated after the final laser spot of the array has passed.

The present inventors have become aware that such known processes and methodology using multiple passes of multiple beams may not be optimised for efficiently removing the material in a thick wafer.

This problem is illustrated in FIG. 7, which schematically shows a sectional view of a wafer 2, taken along the axis of a cut line 6 (see FIG. 5 for example), during a cutting process. Four separate laser beams 20A-D, corresponding to the four laser spots 11A-D of FIG. 6, are arranged to ablate semiconductor material as they move in a direction D relative to the wafer. Each successive laser beam 20A-D will be operative to ablate the wafer to a successively greater depth. The first laser beam 20A has the greatest ablation effect, i.e. it removes the greatest quantity of semiconductor material, since its focal point, where laser energy and hence ablation is concentrated, lies within the semiconductor material. The following laser beams 20B-D have their focal points located in the space left after ablation by the first laser beam 20A. To further illustrate this, FIG. 8 schematically shows the cut line of FIG. 7 along a section orthogonal to the cut line. It can be seen that this known method leads to inefficient cutting.

The present invention seeks to provide a methodology and associated apparatus for more efficient laser cutting using multiple laser beams, particularly for so-called thick wafers.

In accordance with the present invention this aim is achieved by implementing a laser cutting process in which multiple spots are focused at multiple levels within the body of the semiconductor wafer.

The process has application both for scribing and full singulation of wafers.

### SUMMARY OF THE INVENTION

In accordance with a first aspect of the present invention there is provided a laser cutting apparatus for cutting a semiconductor wafer along a cut line of the wafer, comprising:
a planar wafer support surface having a plane operative to support a semiconductor wafer thereon in use,
a laser supply operative to produce a plurality of output laser beams,
a beam focuser located in an optical path of each output laser beam operative to focus each said laser beam at a respective focal point, the wafer support surface being movable relative to the beam focuser in a direction parallel to the plane of the wafer support surface, and
an actuator operative to relatively move the wafer support surface and beam focuser in a direction parallel to the plane of the wafer support surface so that in use the focal point of each output laser beam follows the cut line of the wafer during said relative movement,
wherein the focal point of at least one output laser beam is located at a different distance from the plane of the wafer support surface than the focal point of at least one other output laser beam.

The laser supply may comprise a laser source operative to emit a source laser beam along an optical path and a beam splitter located along the optical path of the source laser beam to split the source laser beam into the plurality of output laser beams. In this case, the beam splitter may comprise a diffractive optical element. The diffractive optical element may be operative to produce at least two output laser beams having different divergences and/or to produce at least two output laser beams having different propagation directions.

Alternatively, the laser supply may comprise a plurality of laser sources, each operative to produce a respective output laser beam. In this case, the apparatus may comprise a plurality of beam focusers, each located along the optical path of a respective laser output beam.

With any of the above-described apparatuses, the focal point of each output laser beam may be located within the semiconductor wafer in use, such that different output laser beams have respective focal points at different depths within the semiconductor wafer.

With any of the above-described apparatuses, the plurality of output laser beams may form an array, with the focal point of each output laser beam in the array being spaced in the direction parallel to the plane of the wafer support surface. In this case, the arrangement of output laser beam focal points within the array may form a linear profile, such that the spacing of adjacent focal points in the direction parallel to the plane of the wafer support surface is directly proportional to the spacing of those adjacent focal points in the direction orthogonal to the plane of the wafer support surface. The adjacent output laser beam focal points within the array may be spaced by a Rayleigh length of the output laser beams. In an alternative case, the arrangement of output laser beam focal points within the array may form a non-linear profile, such that the spacing of adjacent focal points in the direction parallel to the plane of the wafer support surface is not directly proportional to the spacing of those adjacent focal points in the direction orthogonal to the plane of the wafer support surface.

In accordance with a second aspect of the present invention there is provided a method of cutting a planar semiconductor wafer along a cut line of the wafer, comprising the steps of:
a) supporting the semiconductor wafer within a laser cutting apparatus,
b) directing a plurality of laser beams at the semiconductor wafer in a propagation direction substantially orthogonal to the plane of the semiconductor wafer,
c) focusing the plurality of laser beams so that respective focal points of said plurality of laser beams are located within the semiconductor wafer, such that the focal point of at least one laser beam is located at a different depth of the semiconductor wafer than the focal point of at least one other output laser beam, and
d) relatively moving the semiconductor wafer and the plurality of laser beams in a direction parallel to the plane of the semiconductor wafer such that the focal point of each laser beam follows the cut line of the wafer, so that the semiconductor wafer is cut along the cut line.

Step c) may comprise focusing the plurality of laser beams such that the spacing of adjacent focal points in the direction parallel to the plane of the wafer support surface is directly proportional to the spacing of those adjacent focal points in the direction orthogonal to the plane of the wafer support surface, such that the arrangement of laser beam focal points forms a linear profile. In this case, the adjacent output laser beam focal points may be spaced by a Rayleigh length of the laser beams.

Alternatively, step c) may comprise focusing the plurality of laser beams such that the spacing of adjacent focal points in the direction parallel to the plane of the wafer support surface is not directly proportional to the spacing of those adjacent focal points in the direction orthogonal to the plane of the wafer support surface, such that the arrangement of laser beam focal points forms a non-linear profile.

Other specific aspects and features of the present invention are set out in the accompanying claims.

### BRIEF DESCRIPTION OF THE DRAWINGS

The invention will now be described with reference to the accompanying drawings (not to scale), in which:

FIG. 1 schematically shows a sectional view of part of a known laser cutting apparatus;

FIG. 2 schematically shows the cutting apparatus of FIG. 1 during a cutting process;

FIG. 3 schematically shows a sectional view of alternative known laser cutting apparatus used for cutting foil-back wafer;

FIG. 4 schematically shows the cutting apparatus of FIG. 3 during a cutting process;

FIG. 5 schematically shows a top view of a wafer, illustrating a known cutting methodology;

FIG. 6 schematically shows an enlarged view of the wafer of FIG. 5;

FIG. 7 schematically shows a sectional view of a cut line of a wafer, cut with a known cutting apparatus;

FIG. 8 schematically shows the cut line of FIG. 7, along a section orthogonal to the cut line;

FIG. 9 schematically shows a sectional view of a cut line of a wafer, cut with a cutting apparatus in accordance with an embodiment of the present invention;

FIG. 10 schematically shows the cut line of FIG. 9, along a section orthogonal to the cut line;

FIGS. 11A-D schematically show sectional views along a cut line of a wafer, illustrating exemplary profiles of focal points in accordance with the present invention;

FIG. 12 schematically shows a laser cutting apparatus in accordance with an embodiment of the present invention;

FIGS. 13A, B schematically show DOEs suitable for use with the present invention;

FIG. 14 schematically shows part of a laser cutting apparatus in accordance with another embodiment of the present invention; and

FIG. 15 schematically shows part of a laser cutting apparatus in accordance with a further embodiment of the present invention.

### DETAILED DESCRIPTION OF THE PREFERRED EMBODIMENTS OF THE INVENTION

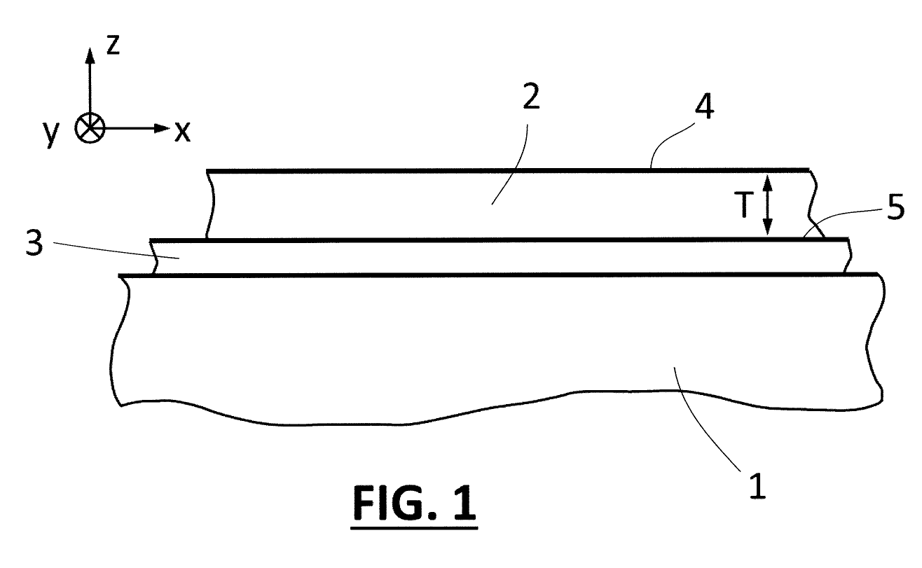

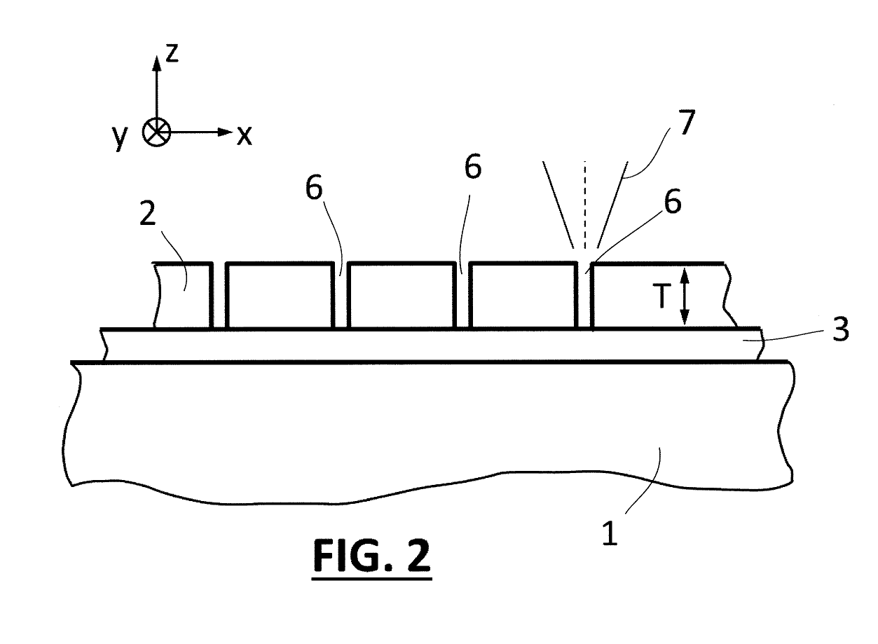

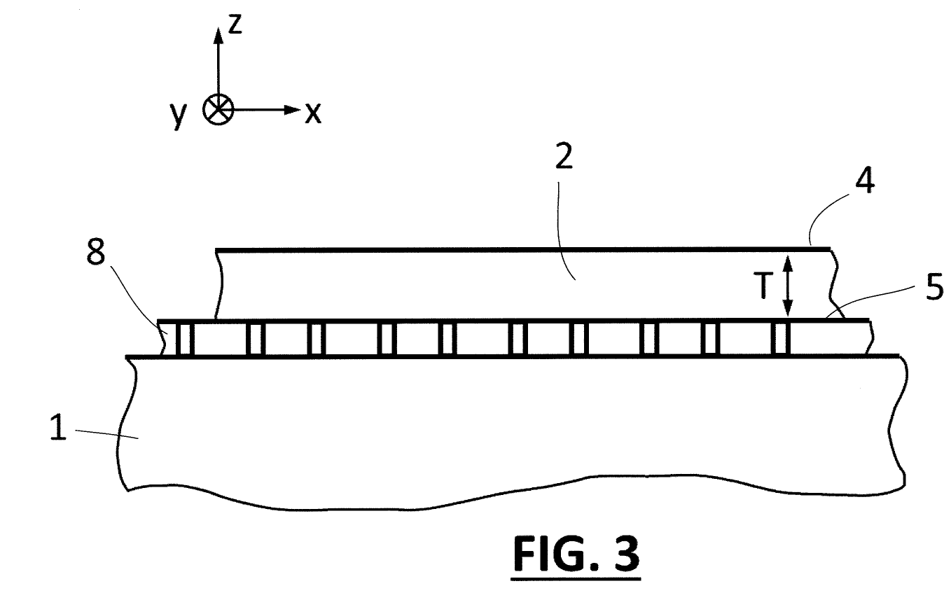

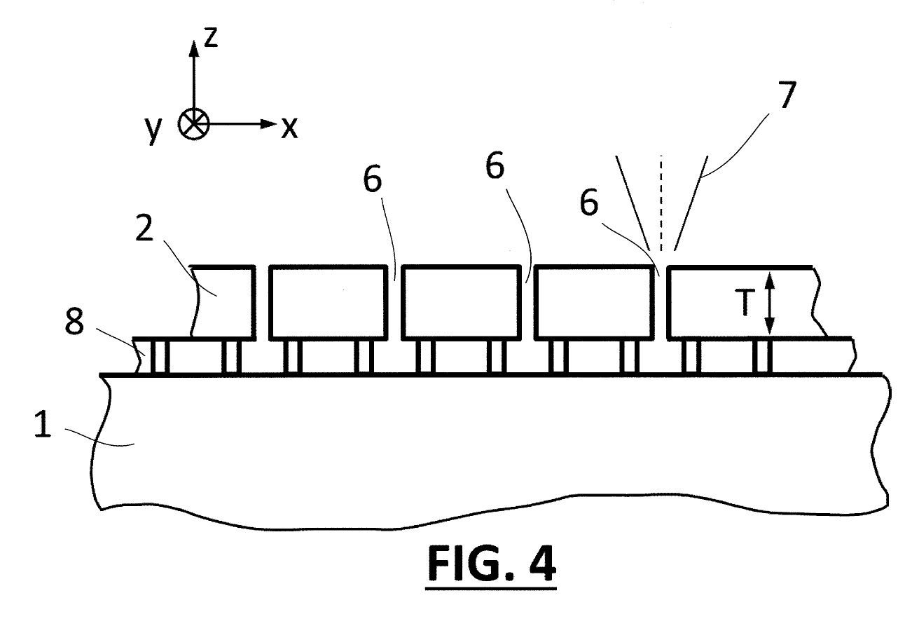

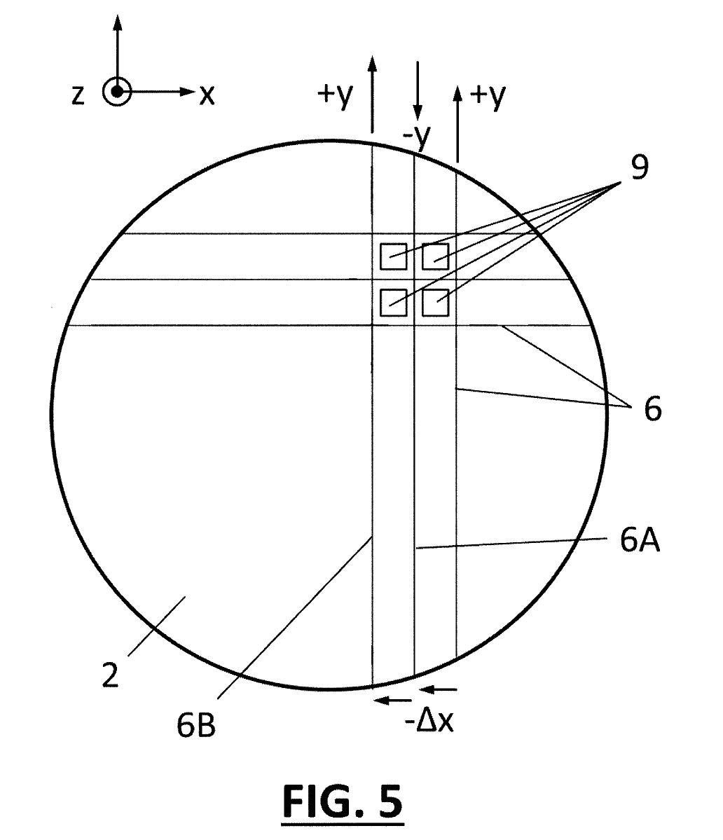

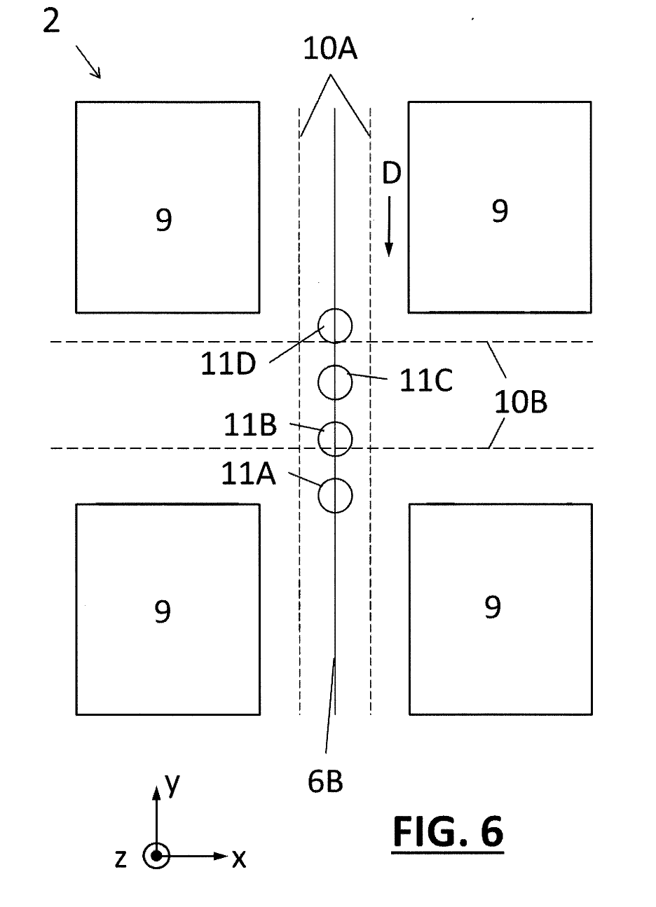

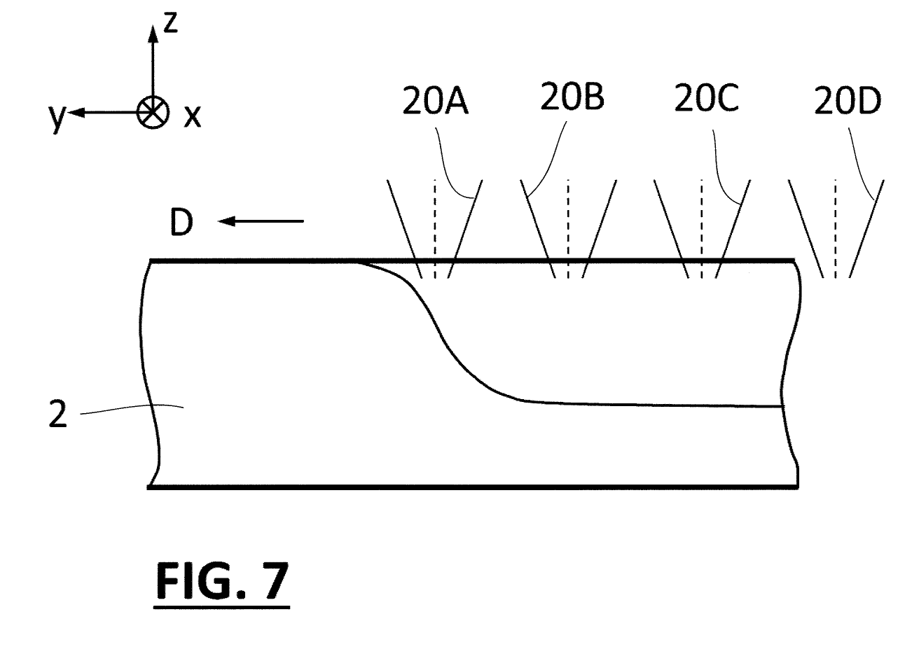

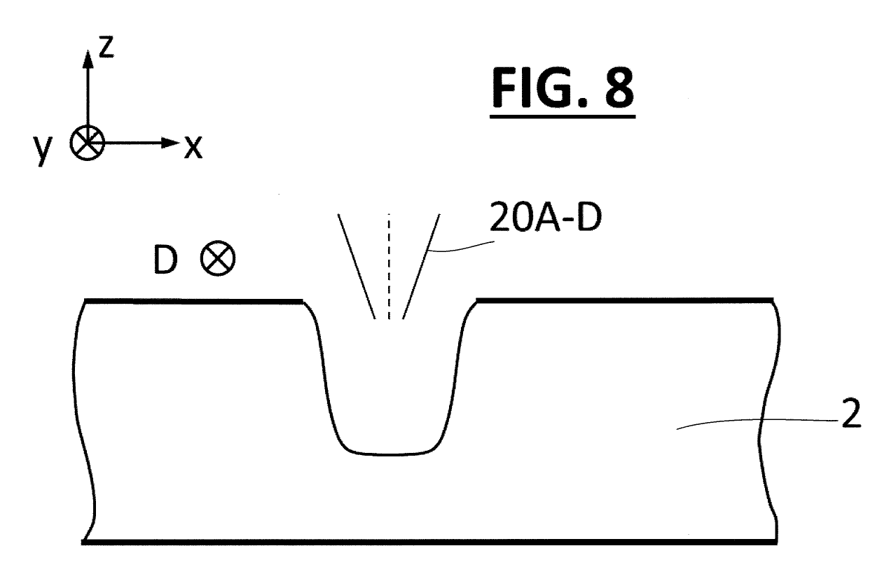

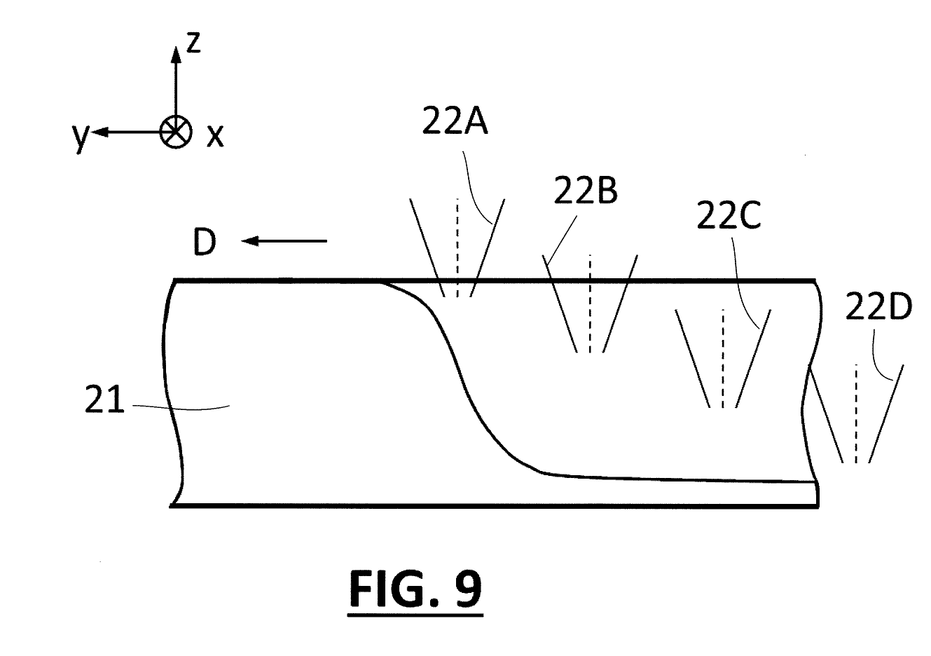

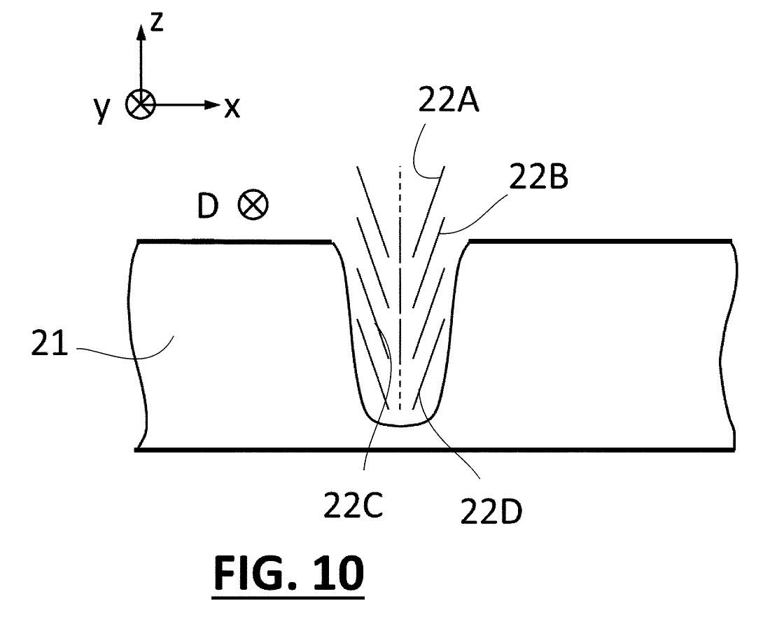

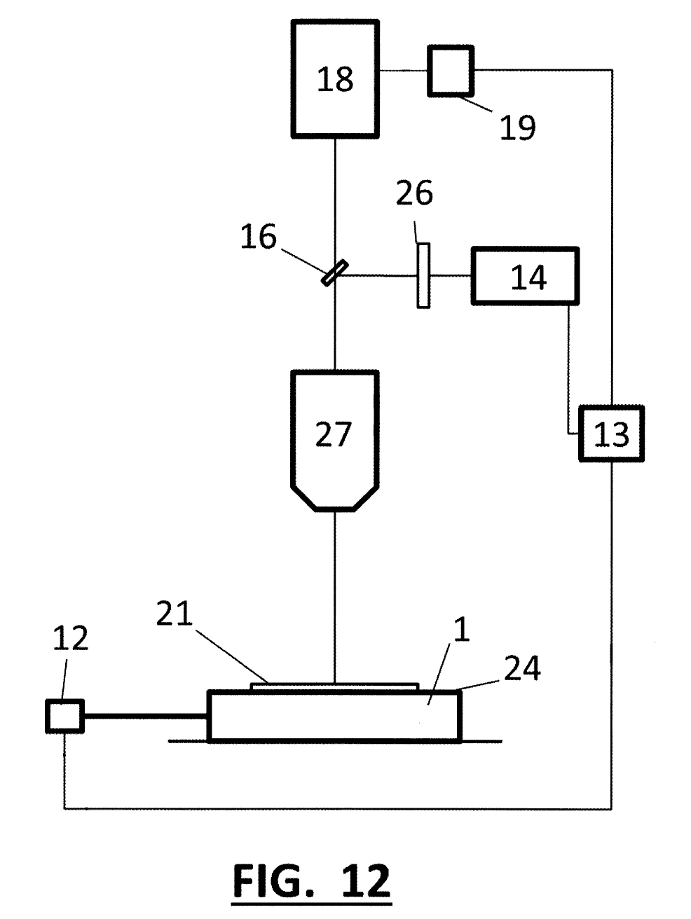

FIGS. 9 and 10 show views similar to those of FIGS. 7 and 8 respectively, but with an improved laser beam focal point profile in accordance with an embodiment of the present invention. Here, an array of four output laser beams 22A-D illuminates a planar semiconductor wafer 21 to cause ablation of the same along a cut line. Although not shown for clarity, the wafer 21 is supported on a planar wafer support surface (24, see FIG. 12). The semiconductor wafer 21 may be provided with a carrying foil (not shown) similar to that shown in FIG. 1, or alternatively the wafer support surface 24 may include a jig (not shown) on which the wafer 21 is supported, similar to the arrangement shown in FIG. 3. The respective focal points of the laser beams 22A-D are spaced not only in the Y direction along the cut line, but also in the Z direction so that they are located at different distances relative to the wafer support surface. Moreover, the focal points all lie within the body of the uncut wafer. In this way, the focal points are positioned to be closer to the remaining material to be ablated by that respective laser beam.

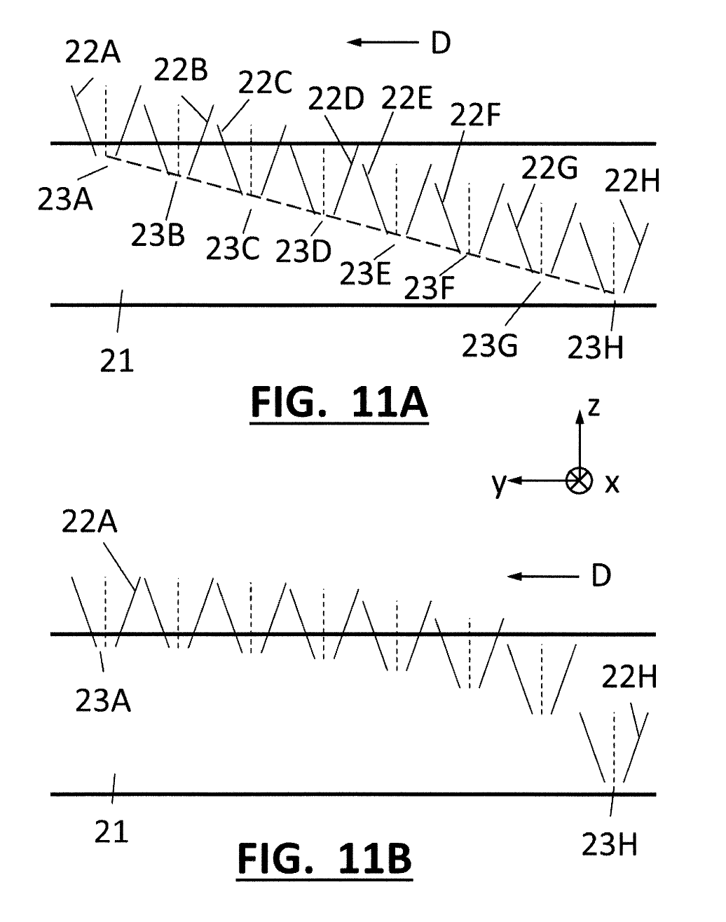

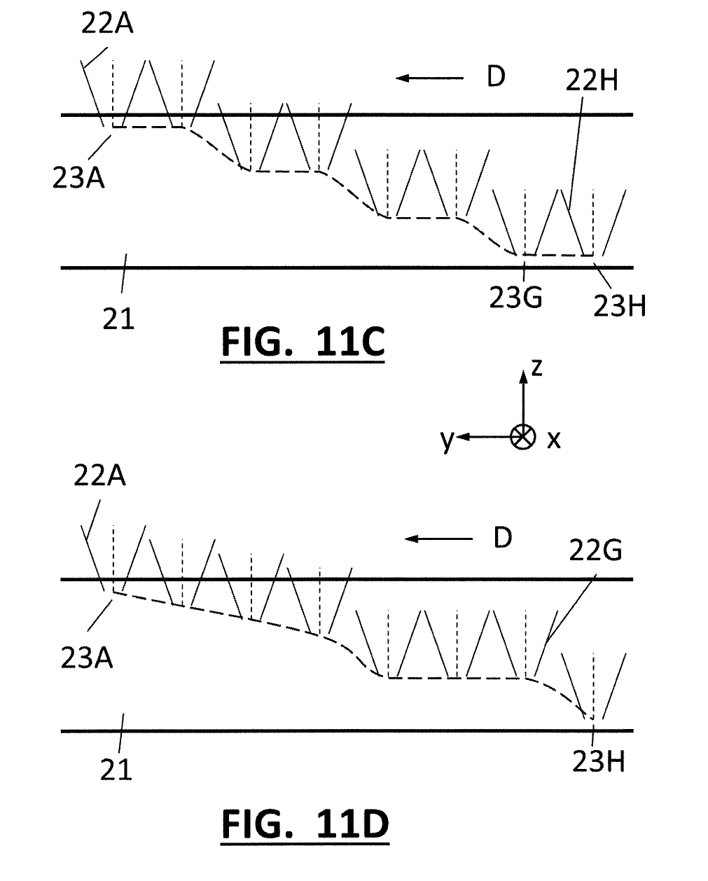

FIGS. 11A-D schematically show sectional views along a cut line of a planar semiconductor wafer 21, illustrating exemplary profiles of focal points in accordance with the present invention. In these figures, the semiconductor wafer 21 is shown being cut by a linear array of eight output laser beams 22A-H in a cutting direction D. Laser beam 22A is therefore the leading laser beam of the array. Each output laser beam 22A-H is focused to a respective focal point 23A-H. The focal point of each output laser beam in the array is spaced from another output laser beam in a direction parallel to the plane of the wafer support surface.

The laser beams 22A-H undergo focusing such that the focal point of at least one output laser beam is located at a different distance from the plane of the wafer support surface 24 than the focal point of at least one other output laser beam. In preferred embodiments, such as those shown in FIGS. 11A-D, each of the laser beams 22A-H has a focal point 23A-H located within the semiconductor wafer 21 in use, such that different output laser beams have respective focal points at different depths within the semiconductor wafer.

The pitch between adjacent beams of the array in the Y direction may for example be in the range from about 5 μm to about 400 μm. The height differences in the Z-direction between adjacent beams may for example be in the range from about 5 μm to about 100 μm, which may be dependent on the thickness of the wafer 21.

In FIG. 11A, the focal points 23A-H are arranged in a linear profile, shown as a dotted line, such that the spacing of adjacent focal points in the direction parallel to the plane of the wafer support surface 24 is directly proportional to the spacing of those adjacent focal points in the direction orthogonal to the plane of the wafer support surface 24. Leading laser beam 22A is focused at a point near to the upper major surface of the semiconductor wafer 21, with each successive laser beam in the array being focused at successively lower points, until trailing laser beam 22H is focused at a point near to the lower major surface of the semiconductor wafer 21. With such a profile, it is clear that each laser beam will act to ablate semiconductor material at successively lower depths along the cut line. The focal point 23H of trailing beam 22H is selected to be sufficiently close to the lower surface of the semiconductor wafer 21 to ensure complete ablation of the semiconductor material throughout the depth of the cut line, thus providing singulation. Advantageously, the adjacent output laser beam focal points within the array are spaced by a Rayleigh length of the output laser beams.

In FIGS. 11B-D, the focal points 23A-H are arranged in non-linear profiles, such that the spacing of adjacent focal points in the direction parallel to the plane of the wafer support surface 24 is not directly proportional to the spacing of those adjacent focal points in the direction orthogonal to the plane of the wafer support surface.

In FIG. 11B, the spacings in the Z-direction between focal points of adjacent laser beams increases in a non-directly proportional arrangement from the leading beam to the trailing beam.

In FIG. 11C, a stepped profile is used, in which adjacent pairs of laser beams have their focal points at the same distance from the wafer support table, each pair having their focal points focused at successively lower points, until trailing laser beams 22H and its immediate precursor 22G are focused at a point near to the lower major surface of the semiconductor wafer 21.

In FIG. 11D, a more irregular profile is shown, the leading four laser beams 22A-22D having their focal points arranged in a linear profile, with the next three laser beams 22E-22G having their focal points at the same distance from the wafer support surface 24, and finally the trailing laser beam 22H being focused at a point near to the lower major surface of the semiconductor wafer 21.

FIG. 12 schematically shows a laser cutting apparatus in accordance with the present invention. A planar semiconductor wafer 21 is supported on a wafer support surface 24 of a wafer table 1, which forms part of a moveable stage assembly, controlled by a motion controller 12, with wafer 21 being held thereon by peripheral clamping or the like. The stage assembly comprises, for example, two separate linear motors (not shown) for independently driving the wafer table 1 along the X and Y axes. The wafer table 1 is caused to float smoothly over a reference surface (such as a polished stone surface) in the X-Y plane, for example with the aid of an air bearing or magnetic bearing (not shown). The exact position of the wafer table 1 is monitored and controlled with the aid of positioning instruments such as interferometers or linear encoders, for example (not shown). Focus control and/or level sensing systems (not shown) are employed to ensure that the surface of the wafer 21 is maintained at a desired level with respect to the laser projection system.

A pulsed laser source 14 is provided to emit a pulsed laser beam that propagates along an optical path. The laser source 14 is connected to a controller 13, such as a processor or computer, that can be used among other things to control laser parameters such as the pulse duration, pulse repetition rate and power or fluence of the beam.

A diffractive optical element (DOE) 26 is located along the optical path to split the laser beam into multiple output laser beams having different beam divergence angles, as will be described in more detail below.

A beam splitter/combiner 16, such as a partially-silvered or dichroic mirror, directs the output laser beams toward the wafer 21, while also permitting reflected light to be passed to a vision system (see below).

A beam focuser 27, such as a lens or concave mirror or the like, collects the output laser beams and focuses them for projection onto the wafer 21. At the point of impingement of the beams upon the wafer 21, light spots are formed according to the individual beam properties. Aberration and/or distortion correction may also be performed at this stage, as is known in the art. The beam focuser 27 is operative to focus the output laser beams at the required distance from the wafer support surface 24.

A vision system 18, optically connected to a digital camera 19, receives reflected light from the beam splitter/combiner 16. This is used to perform alignment and tracking operations of the beams relative to the surface of the wafer 21 as is known in the art. The use of a beam splitter/combiner 16 permits the camera 19 to be used in an “on-axis” arrangement, whereby it can observe the wafer 21 along an axis substantially co-linear with the beam. A portion of light emanating from the surface 4, due to reflection, will pass through the beam splitter/combiner 16 and be directed to the camera 19.

The controller 13 is used for controlling and processing images captured by the camera 19, and adapts the operation of the laser source 14 depending on the received image information.

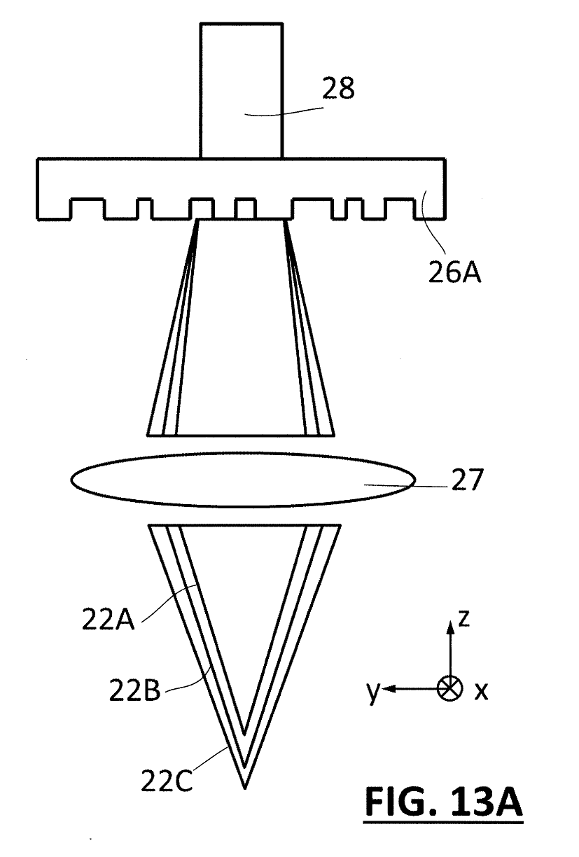

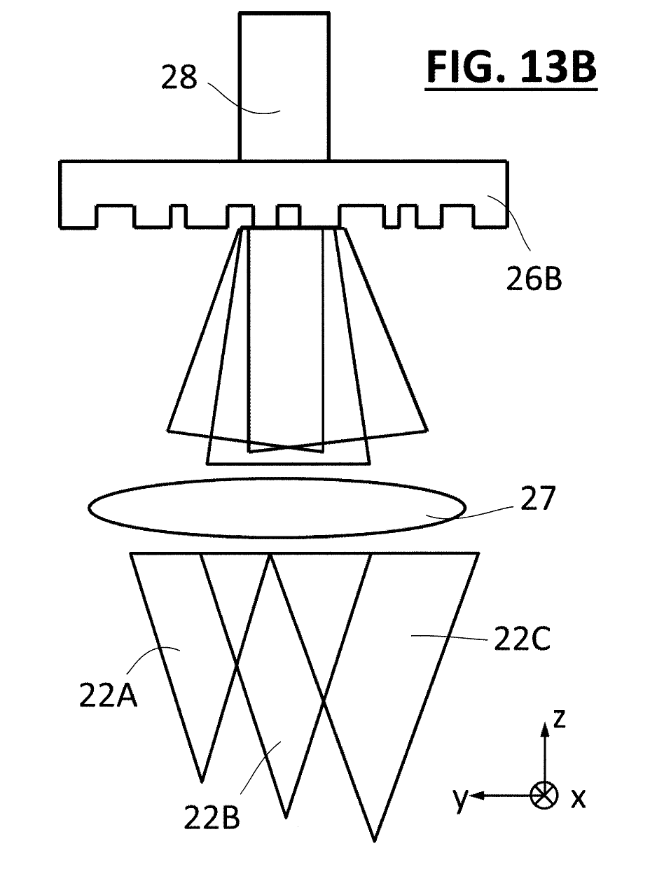

FIGS. 13A-B schematically show two alternative DOE designs 26A, 26B suitable for use with the laser cutting apparatus described above. FIG. 13A shows a DOE 26A with which spots with different focal point depths can be realized by splitting and altering an incoming collimated source laser beam 28 into multiple output beams 22A-C of different divergences. The split output beams 22A-C have the same beam angle, and so propagate along the same longitudinal axis. If the output beams are to be spatially separated in the Y direction to form an array, then they may be passed through an additional DOE (not shown) as required. The output laser beams 22A-C pass through beam focuser 27, in this case a lens, which focuses the beams. Due to the differing divergences, the resulting focal points are spaced in the Z direction.

FIG. 13B shows an alternative DOE 26B which produces output beams with both different divergences and different beam angles, such that they propagate in different directions. When the output beams are focused by beam focuser 27, in this case a lens, an array of output laser beams 22A-C are produced, with their respective focal points being spaced in the Y direction. Due to the differing divergences, the resulting focal points are also spaced in the Z direction.

It is possible to design and fabricate DOEs to produce beam divergences and angular control with accuracies in the order of micro-radians. For focal lengths of 1 mm to 200 mm typically used in laser material processes, the design and fabrication errors would contribute to a geometric errors in the X, Y and Z axes of less than 4 μm.

The design of the DOE requires the simulation of an inverted light propagation from the plane in which the pattern is to be created back to the plane of the DOE. The 3D spot distribution is firstly arranged based on the application need. A far-field electromagnetic wave profile is then calculated for an inverted light propagation to achieve the required phase change of an incoming coherent Gaussian laser beam. In designing the focused laser spots at different focus levels, the far-field information can be defined at certain nominal focus positions, whereby individual spots have differing divergences to reflect their corresponding focus positions.

The above-described embodiments make use of a DOE to act on optical rays propagating through free-space. However, various alternatives are possible within the scope of the present invention.

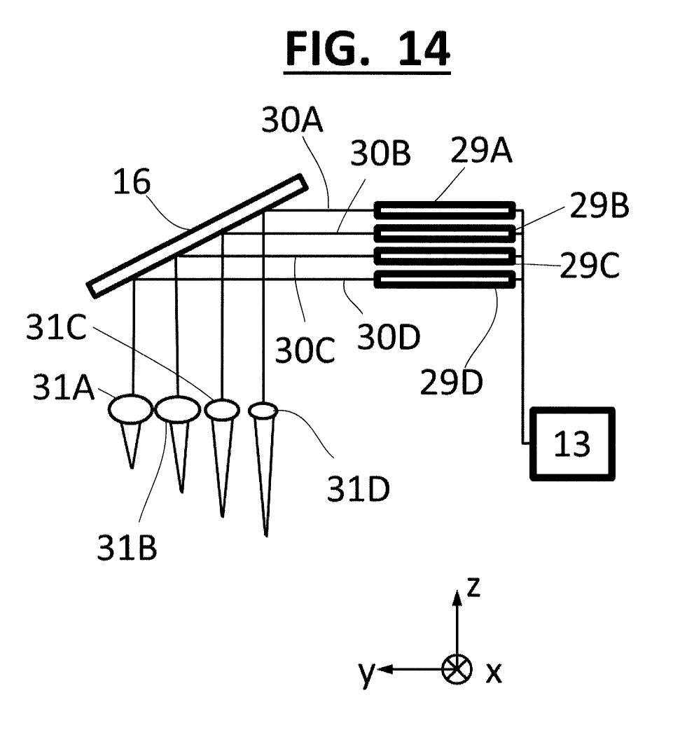

An alternative embodiment of the present invention is schematically shown in FIG. 14. For clarity, only components of the illumination system are shown, and it should be understood that the wafer support table and inspection system are as previously described.

Here, rather than splitting a single source laser beam to produce a plurality of output laser beams, a total of four laser sources 29A-D are provided, their outputs being controlled by controller 13. These are arranged to emit similar and generally parallel laser beams 30A-D. These are directed by beam splitter/combiner 16 towards respective beam focusers comprising individual lenses 31A-D. The lenses 31A-D have differing focal lengths, such that each output laser beam has a focal point at a different distance from the wafer support surface (not shown) in use.

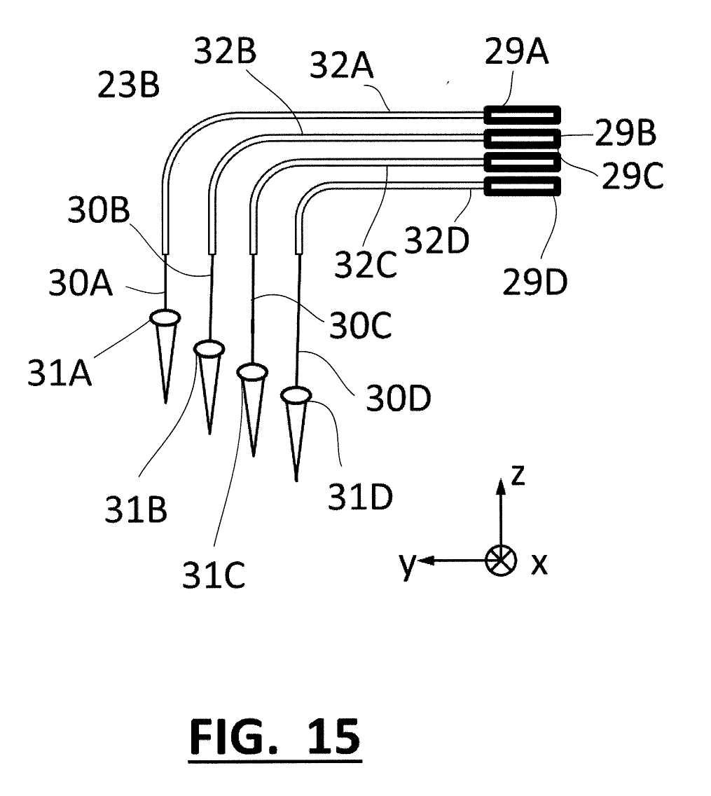

A further alternative embodiment of the present invention is schematically shown in FIG. 15. For clarity, only components of the illumination system are shown, and it should be understood that the wafer support table, inspection system and laser controller are as previously described.

Here, similar to the previous embodiment, a total of four laser sources 29A-D are provided, their outputs being controlled by a controller (not shown). These are arranged to emit similar laser beams 30A-D. The laser beams 30A-D are guided by means of respective optical fibers 32A-D towards respective beam focusers comprising individual lenses 31A-D. The lenses 31A-D here have identical focal lengths, but the lenses are spaced in the Z direction, such that each output laser beam has a focal point at a different distance from the wafer support surface (not shown) in use. This embodiment therefore enables the Y-axis position of the laser spots to be precisely arranged without the use of diffractive elements, so that the ease of adjustment may be improved.

The above-described embodiments are exemplary only, and other possibilities and alternatives within the scope of the invention will be apparent to those skilled in the art.

For example, the beam focuser used in the embodiments shown in FIGS. 14 and 15 are freely interchangeable.

While the above-described embodiments show laser spot arrays with a similar Y-direction spacing, this spacing could be selected and/or varied as appropriate.

Optical fibers could be used to guide laser beams throughout any part of their optical paths, rather than free-space transmission.

The beam focuser (and optionally the laser supply) may be moved while the wafer support surface remains stationary, in order to effect cutting.

The apparatus and method of the present invention may be used both for singulation and scribing processes.

### REFERENCE NUMERALS USED

1—wafer table
2—semiconductor wafer
3—foil
4—first major surface
5—second major surface
6, 6A, 6B—cut lines
7—laser beam
8—jig
9—semiconductor devices
10A, 10B—dicing streets
11A-D—laser spots
12—motion controller
13—controller
14—laser source
15—beam divider
16—beam splitter/combiner
17—beam focuser
18—vision system
19—camera
20A-D—laser beams
21—semiconductor wafer
22A-H—output laser beams
23A-H—focal points
24—wafer support surface
26—diffractive optical element
27—beam focuser
28—source laser beam
29A-D—laser sources
30A-D—source laser beams
31A-D—lenses
32A-D—optical fibers
33A-D—lenses
D—cutting direction
T—wafer thickness

1. A laser cutting apparatus for cutting a semiconductor wafer along a cut line of the wafer, comprising:
a planar wafer support surface having a plane operative to support a semiconductor wafer thereon in use,
a laser supply operative to produce a plurality of output laser beams,
a beam focuser located in an optical path of each output laser beam operative to focus each said laser beam at a respective focal point, the wafer support surface being movable relative to the beam focuser in a direction parallel to the plane of the wafer support surface, and
an actuator operative to relatively move the wafer support surface and beam focuser in a direction parallel to the plane of the wafer support surface so that in use the focal point of each output laser beam follows the cut line of the wafer during said relative movement,
wherein the focal point of at least one output laser beam is located at a different distance from the plane of the wafer support surface than the focal point of at least one other output laser beam.

2. The laser cutting apparatus of claim 1, wherein the laser supply comprises a laser source operative to emit a source laser beam along an optical path and a beam divider located along the optical path of the source laser beam to split the source laser beam into the plurality of output laser beams.

3. A laser cutting apparatus according to claim 2, wherein the beam divider comprises a diffractive optical element.

4. The laser cutting apparatus of claim 3, wherein the diffractive optical element is operative to produce at least two output laser beams having different divergences.

5. The laser supply apparatus of claim 3, wherein the diffractive optical element is operative to produce at least two output laser beams having different propagation directions.

6. The laser cutting apparatus of claim 1, wherein the laser supply comprises a plurality of laser sources, each operative to produce a respective output laser beam.

7. The laser cutting apparatus of claim 6, comprising a plurality of beam focusers, each located along the optical path of a respective laser output beam.

8. The laser cutting apparatus of claim 1, wherein the focal point of each output laser beam is located within the semiconductor wafer in use, such that different output laser beams have respective focal points at different depths within the semiconductor wafer.

9. The laser cutting apparatus of claim 1, wherein the plurality of output laser beams form an array, with the focal point of each output laser beam in the array being spaced in the direction parallel to the plane of the wafer support surface.

10. The laser cutting apparatus of claim 9, wherein the arrangement of output laser beam focal points within the array form a linear profile, such that the spacing of adjacent focal points in the direction parallel to the plane of the wafer support surface is directly proportional to the spacing of those adjacent focal points in the direction orthogonal to the plane of the wafer support surface.

11. The laser cutting apparatus of claim 10, wherein the adjacent output laser beam focal points within the array are spaced by a Rayleigh length of the output laser beams.

12. The laser cutting apparatus of claim 9, wherein the arrangement of output laser beam focal points within the array form a non-linear profile, such that the spacing of adjacent focal points in the direction parallel to the plane of the wafer support surface is not directly proportional to the spacing of those adjacent focal points in the direction orthogonal to the plane of the wafer support surface.

13. A method of cutting a planar semiconductor wafer along a cut line of the wafer, comprising the steps of:
a) supporting the semiconductor wafer within a laser cutting apparatus,
b) directing a plurality of laser beams at the semiconductor wafer in a propagation direction substantially orthogonal to the plane of the semiconductor wafer,
c) focusing the plurality of laser beams so that respective focal points of said plurality of laser beams are located within the semiconductor wafer, such that the focal point of at least one laser beam is located at a different depth of the semiconductor wafer than the focal point of at least one other output laser beam, and
d) relatively moving the semiconductor wafer and the plurality of laser beams in a direction parallel to the plane of the semiconductor wafer such that the focal point of each laser beam follows the cut line of the wafer, so that the semiconductor wafer is cut along the cut line.

14. The method of claim 13, wherein step c) comprises focusing the plurality of laser beams such that the spacing of adjacent focal points in the direction parallel to the plane of the wafer support surface is directly proportional to the spacing of those adjacent focal points in the direction orthogonal to the plane of the wafer support surface, such that the arrangement of laser beam focal points forms a linear profile.

15. The method of claim 14, wherein the adjacent output laser beam focal points are spaced by a Rayleigh length of the laser beams.

16. The method of claim 13, wherein step c) comprises focusing the plurality of laser beams such that the spacing of adjacent focal points in the direction parallel to the plane of the wafer support surface is not directly proportional to the spacing of those adjacent focal points in the direction orthogonal to the plane of the wafer support surface, such that the arrangement of laser beam focal points forms a non-linear profile.
